(19) United States
(12) Patent Application Publication
(10) Pub. No.: US 2024/0316914 A1
(43) Pub. Date: Sep. 26, 2024

(54) Curing of Flexo Printing Elements Using UV LED Systems

(71) Applicant: MacDermid Graphics Solutions, LLC, Waterbury, CT (US)

(72) Inventors: Kyle P. Baldwin, Acworth, GA (US); Brian Cook, Rowell, GA (US)

(21) Appl. No.: 18/186,602

(22) Filed: Mar. 20, 2023

(51) Int. Cl. B41C 1/10

(52) U.S. Cl. CPC B41C 1/10

(57) ABSTRACT

A method of flood exposing a photocurable printing blank to actinic radiation from a UV light source to crosslink and cure the photocurable printing blank. The photocurable printing blank includes a support, at least one photocurable layer upon the support, wherein the at least one photocurable layer is capable of being selectively crosslinked and cured upon exposure to actinic radiation at a desired wavelength. The photocurable printing blank is subjected to flood exposure by positioning the photocurable printing blank in an exposure unit that includes a plurality of UV LED light tubes arranged at a distance from a surface of the photocurable printing blank.

### FIELD OF THE INVENTION

The present invention relates generally to a method of curing flexographic printing elements using UV LED light.

### BACKGROUND OF THE INVENTION

Flexography is a method of printing that is commonly used for high-volume runs. Flexography is employed for printing on a variety of substrates such as paper, paperboard stock, corrugated board, films, foils and laminates. Newspapers and grocery bags are prominent examples. Coarse surfaces and stretch films can be economically printed only by means of flexography.

The demands placed on flexographic printing plates are considerable and it is highly desirable that flexographic printing plates work well under a wide range of conditions. For example, the printing plates should be able to impart their relief image to a wide range of substrates, including cardboard, coated paper, newspaper, calendared paper, and polymeric films such as polypropylene. Importantly, the image should be transferred quickly and with fidelity, for as many prints as the printer desires to make. A flexographic printing plate must also have sufficient flexibility to wrap around a printing cylinder yet be strong enough to withstand the rigors experienced during a typical printing process. The printing plate should exhibit a low hardness to facilitate ink transfer during printing. It is also important that the surface of the printing plate be dimensionally stable during storage. In addition, the printing plate must also have a relief image that has a chemical resistance against the aqueous-based or alcohol-based inks that are typically used in flexographic printing. Finally, it is also highly desirable that the physical and printing properties of the printing element are stable and do not change during printing.

Flexographic printing plates include image elements raised above open areas. A typical flexographic printing plate, as delivered by its manufacturer, is a multilayered article made of, in order, a backing or support layer; one or more unexposed photocurable layers; optionally a protective layer or slip film; and often, a protective cover sheet.

The support (or backing) layer lends support to the plate. The support layer can be formed from a transparent or opaque material such as paper, cellulose film, plastic, or metal. Preferred materials include sheets made from synthetic polymeric materials such as polyesters, polystyrene, polyolefin, polyamides, and the like, including polyethylene terephthalate (PET), polyethylene naphthalate (PEN), and polybutylene terephthalate (PBT). The support may be in sheet form or in cylindrical form, such as a sleeve. One widely used support layer is a flexible film of polyethylene terephthalate.

The photocurable layer(s) can include any of the known photopolymers, monomers, initiators, reactive or non-reactive diluents, fillers, processing aids, UV absorbers and dyes. The term “photocurable” refers to a composition which undergoes polymerization, cross-linking, or any other curing or hardening reaction in response to actinic radiation with the result that the unexposed portions of the material can be selectively separated and removed from the exposed (cured) portions to form a three-dimensional relief pattern of cured material. Exemplary photocurable materials include those disclosed in European Patent Application Nos. 0 456 336 A2 and 0 640 878 A1 to Goss et al., British Patent No. 1,366,769, U.S. Pat. No. 5,223,375 to Berrier et al., U.S. Pat. No. 3,867,153 to MacLahan, U.S. Pat. No. 4,264,705 to Allen, U.S. Pat. Nos. 4,323,636, 4,323,637, 4.369.246, and 4,423,135 all to Chen et al., U.S. Pat. No. 3,265,765 to Holden et al., U.S. Pat. No. 4,320,188 to Heinz et al., U.S. Pat. No. 4,427,759 to Gruetzmacher et al., U.S. Pat. No. 4,622,088 to Min, and U.S. Pat. No. 5,135,827 to Bohm et al., the subject matter of each of which is herein incorporated by reference in its entirety. More than one photocurable layer may also be used. The photocurable layer(s) may be applied directly on the support or may be applied on top of an adhesion layer and/or resilient under layer.

Photocurable materials generally cross-link (cure) and harden through radical polymerization in at least some actinic wavelength region. As used herein, “actinic radiation” refers to radiation that is capable of polymerizing, crosslinking and/or curing the photocurable layer. Actinic radiation includes, for example, amplified (e.g., laser) and non-amplified light, particularly in the UV and violet wavelength regions.

The slip film is a thin layer, which protects the photopolymer from dust and increases its ease of handling. In a conventional (i.e., “analog”) plate making process, the slip film is transparent to UV light. The printer peels the cover sheet off the printing plate blank, and places a negative on top of the slip film layer. The plate and negative are then subjected to flood-exposure by UV light through the negative. The areas exposed to the light cure, or harden, and the unexposed areas are removed (developed) to create the relief image on the printing plate. In the alternative, a negative may be placed directly on the at least one photocurable layer.

In a “digital” or “direct to plate” process, a laser is guided by an image stored in an electronic data file, and is used to create an in situ negative in a digital (i.e., laser ablatable) masking layer, which is generally a slip film which has been modified to include a radiation opaque material. Portions of the laser ablatable layer are then ablated by exposing the masking layer to laser radiation at a selected wavelength and power of the laser. Thereafter, the at least one photocurable layer with the in situ negative thereon, is subjected to flood-exposure by UV light through the in situ negative. The areas exposed to the light cure, or harden, and the unexposed areas are removed (developed) to create the relief image on the printing plate. Examples of laser ablatable layers are disclosed, for example, in U.S. Pat. No. 5,925,500 to Yang et al., and U.S. Pat. Nos. 5,262,275 and 6,238,837 to Fan, the subject matter of each of which is herein incorporated by reference in its entirety.

Processing steps for forming flexographic relief image printing elements typically include the following:
1 Image generation, which may be mask ablation for digital “computer to plate” printing plates or negative production for conventional analog plates;
2) Face exposure through the mask (or negative) to selectively crosslink and cure portions of the photocurable layer not covered by the mask, thereby creating the relief image;
3) Back exposure to sensitize the photocurable layer and create a floor layer in the photocurable layer that establishes the depth of relief;
4) Development to remove unexposed photopolymer by solvent (including water) or dry “thermal” development; and
5) If necessary, post exposure and detackification.

Removable coversheets may be used to protect the photocurable printing element from damage during transport and handling. Useful cover sheets include flexible polymeric films, e.g., polystyrene, polyethylene, polypropylene, polycarbonate, fluoropolymers, polyamide or polyesters. Polyesters, especially polyethylene terephthalate, are commonly used.

Prior to the brief back exposure step (i.e., brief as compared to the imagewise exposure step), an imagewise exposure is performed utilizing the digitally-imaged mask or the photographic negative mask, which is in contact with the photocurable layer and through which actinic radiation is directed.

The type of radiation used is dependent in part on the type of photoinitiator in the photopolymerizable layer. The digitally-imaged mask or photographic negative prevents the material beneath from being exposed to the actinic radiation and hence those areas covered by the mask do not polymerize, while the areas not covered by the mask are exposed to actinic radiation and polymerize. Conventional sources of actinic radiation including carbon arcs, mercury-vapor arcs, fluorescent lamps, electron flash units, electron beam units, photographic flood lamps, and, more recently, UV light emitting diodes (LEDs).

The exposure unit for crosslinking and curing the flexographic relief image printing plate has commonly relied on fluorescent light, and fluorescent tubes are a typical example. The fluorescent tubes may be arranged next to another in one plane in close proximity and parallel to the flexographic relief image printing plate to provide a light source in the exposure unit that covers the entire flexographic printing plate. The number of fluorescent tubes is generally greater than 5 or greater than 10 and may be up to 30 or up to 40 or up to 50. These systems are generally referred to as “bank light systems” or “flood” light systems.

One of the biggest drawbacks to the use of UV fluorescent tubes is that their intensity drops over time, causing customers to constantly adjust their cure times, which also affects the consistency and quality of the cured printing plate. In addition, fluorescent bulbs are changed on a routine basis. Since the bulbs contain mercury, disposal of the bulbs is considered hazardous.

It would be desirable to provide a replacement for a flood light exposure system that relies on fluorescent tubes to provide a system that has greater stability, more consistent light output and a longer lifetime and that does not have issues with regards to bulb disposal.

LEDs are semiconductor devices which use the phenomenon of electroluminescence to generate light. LEDs consist of a semiconducting material doped with impurities to create a p-n junction capable of emitting light as positive holes join with negative electrons when voltage is applied. The wavelength of emitted light is determined by the materials used in the active region of the semiconductor. Typical materials used in semiconductors of LEDs include, for example, elements from Groups (III) and (V) of the periodic table. These semiconductors are referred to as III-V semiconductors and include, for example, GaAs, GaP, GaAsP, AlGaAs, InGaAsP, AlGaInP and InGaN semiconductors. The choice of materials is based on multiple factors including desired wavelength of emission, performance parameters and cost.

LEDs can be created to emit light at wavelengths ranging from a low of about 100 nm to a high of about 900 nm. UV LED light sources emit light at wavelengths between about 300 and about 475 nm, with 365 nm, 390 nm and 395 nm being common peak spectral outputs. When using LED light sources for curing photocurable compositions, the photoinitiator in the photocurable composition is selected to be responsive to the wavelength of light emitted by the LED light source.

LEDs are instant on/off sources requiring no warm-up time, which contributes to LED lamps' low energy consumption. LEDs advantages over fluorescent tubes, include lower power consumption, slower aging, more stable UV output over temperature, and no warmup phase. While UV output of LEDs also decays over the lifetime of an LED, the lifetime of an LED is about one order of magnitude higher than fluorescent tubes. LED output is also much more stable after turning on. LEDs also generate much less heat, with higher energy conversion efficiency, have longer lamp lifetimes, and are essentially monochromatic, emitting a desired wavelength of light which is governed by the choice of semiconductor materials employed in the LED.

Lighting suppliers in the flexographic printing plate industry have created LED light bar systems, which include an array of high intensity LED lights that cure the printing plate in one or more passes. These commercial systems are typically based on relative motion between the photopolymer plate and the light source. Usually, the UV LEDs are arranged in a row that extends over one dimension of the plate while the other dimension is exposed by relative movement between the light source and the plate. That is, the curing devices that incorporate LEDs have generally utilized high intensity UV LEDs that are arranged in an array or an assembly.

For example, the UV LEDs may be arranged in a light bar, in which the light bar and the photocurable printing blank move relative to each other (i.e., the light bar travels over the printing or the plate travels under the light bar), in order to cure the entire plate surface, as described, for example, in U.S. Pat. Pub. No. 2012/0266767 to Klein et al., the subject matter of which is herein incorporated by reference in its entirety. Klein et al. describes both printing sleeves and flat printing plates that may be produced by moving a light exposure unit relative to a printing sleeve or planar printing plate and describes a light exposure unit that includes LED arrays. The light exposure unit can be used to producing printing elements having flat tops and round tops on the same plate using a digital workflow. U.S. Pat. Pub. No. 2013/0242276 to Schadebrodt et al., the subject matter of which is herein incorporated by reference in its entirety, describes a method of producing flexographic printing elements including the steps of exposing the printing element to actinic light at a high intensity with a plurality of UV LEDs and then exposing the printing element to actinic light at a lower intensity from a UV radiation source other than UV-LEDs.

A significant portion of the cost of such systems relates to the mechanics required to create the relative movement between the plate and the UV source. Further costs arise from the need for cooling LEDs, which are necessarily concentrated in a rather small area. Other costs are incurred by the complex driving electronics needed to balance and control the UV output of the LEDs in the system.

In addition, flood light exposure performs better for the formation of flexographic printing dots than multiple passes of a light bar. In addition, the use of multiple passes of a light bar is also significantly slower than the use of flood light exposure. That is, a typical standard flexographic printing plate cures in about 8 to 10 minutes using a conventional flood fluorescent tube exposure system, while the same plate may require 20 to 30 minutes to cure using an LED light bar system.

In order to perform the imagewise exposure step in a relatively short period of time, it has generally been required that the light bar exhibit an extremely high UV output of (e.g., 1 W/cm² or greater) at the plate surface. However, this approach is problematic because it can generate a lot of heat and the rapid cure of the polymer can cause the surface to contract or “cup.” In addition, plates cured with high intensity UV LEDs can actually print with more gain that the same plate cured under a lower intensity UV LED.

It is known that an array of LED lights in a flood pattern can cure flexographic printing plates to make a decent image. U.S. Pat. No. 10,036,956 to Baldwin et al., the subject matter of which is herein incorporated by reference in its entirety, describes a method of flood exposing a photocurable printing blank to actinic radiation from a UV LED light source which includes a high intensity UV LED light source that is modulated to a lower intensity. However, this system requires a mirrored light box to modulate the intensity of the light source which adds both cost and complexity to the system.

The inventors of the present invention have discovered that in a similar manner to the use LED white light tubes as a replacement for fluorescent tube bulbs in residential and office settings, UV LED tube lights can be configured to replace an array of UV LED lights for curing flexographic printing elements.

### SUMMARY OF THE INVENTION

It is an object of the present invention to provide an exposure system for exposing photocurable printing blanks to actinic radiation from UV LEDS.

It is another object of the present invention to provide an exposure system for crosslinking and curing flexographic photocurable printing blanks using UV LED light tubes.

It is still another object of the present invention to provide an exposure system for exposing photocurable printing blanks to UV LED light tubes at a suitable wavelength and intensity to crosslink and cure at least portions of the photocurable printing blank.

To that end, in one embodiment, the present invention relates generally to a method of flood exposing a photocurable printing blank to actinic radiation from a UV light source to crosslink and cure the photocurable printing blank, the photocurable printing blank comprising a support, at least one photocurable layer upon the support, wherein the at least one photocurable layer is capable of being selectively crosslinked and cured upon exposure to actinic radiation at a desired wavelength and wherein the at least one photocurable layer comprises (a) at least one elastomeric binder, (b) at least one ethylenically unsaturated monomer, and (c) a photoinitiator having a favorable absorption profile in the desired wavelength region used for exposing the at least one photocurable layer to actinic radiation, and a photographic negative or digitally imaged mask layer disposed on the at least one photocurable layer; the method comprising the steps of:
a) positioning the photocurable printing blank in an exposure unit, wherein the exposure unit comprises a plurality of UV LED light tubes arranged in the exposure unit at a distance from a surface of the photocurable printing blank, wherein the plurality of UV LED light tubes are capable of exposing the photocurable printing blank to actinic radiation; and
b) flood exposing the photocurable printing blank through the photographic negative or the digitally imaged mask layer to actinic radiation from the plurality of UV LED light tubes;
wherein portions of the at least one photocurable layer not covered by the photographic negative or digitally imaged mask layer crosslink and cure upon exposure to actinic radiation from the UV LED light tubes to create the relief image therein.

### BRIEF DESCRIPTION OF THE FIGURES

FIG. 1 depicts 1% printing dots imaged using an LED light bar of the prior art.

FIG. 2 depicts 1% printing dots imaged using a bank of UV LED light tubes in accordance with the invention.

FIG. 3 depicts 5% printing dots imaged using an LED light bar of the prior art.

FIG. 4 depicts 5% printing dots imaged using a bank of UV LED light tubes in accordance with the invention.

FIG. 5 depicts 50% printing dots imaged using an LED light bar of the prior art.

FIG. 6 depicts 50% printing dots imaged using a bank of UV LED light tubes in accordance with the invention.

FIG. 7 depicts 15 mil reverses imaged using an LED light bar of the prior art.

FIG. 8 depicts 15 mil reversed imaged using a bank of UV LED light tubes in accordance with the invention.

### DETAILED DESCRIPTION OF THE PREFERRED EMBODIMENTS

As used herein, the terms “a” “an,” and “the” refer to both singular and plural referents unless the context clearly dictates otherwise.

As used herein, the term “about” refers to a measurable value such as a parameter, an amount, a temporal duration, and the like and is meant to include variations of +/−15% or less, preferably variations of +/−10% or less, more preferably variations of +/−5% or less, even more preferably variations of +/−1% or less, and still more preferably variations of +/−0.1% or less of and from the particularly recited value, in so far as such variations are appropriate to perform in the invention described herein. Furthermore, it is also to be understood that the value to which the modifier “about” refers is itself specifically disclosed herein.

As used herein, spatially relative terms, such as “beneath,” “below,” “lower” “above.” “upper” and the like, are used for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements of features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly. It is further understood that the terms “front” and “back” are not intended to be limiting and are intended to be interchangeable where appropriate.

As used herein, the terms “comprises” and/or “comprising,” specify the presence of stated features, integers, steps, operations, elements, and/or components, but do not preclude the presence or addition of one or more other features, integers, steps, operations, elements, components, and/or groups thereof.

As used herein for purposes of the present disclosure, the term “LED” refers to an electroluminescent diode or other type of carrier injection/junction-based system that is capable of generating radiation in response to an electric signal. Thus, the term LED includes, but is not limited to, various semiconductor-based structures that emit light in response to current, light emitting polymers, organic light emitting diodes (OLEDs), electroluminescent strips, and the like. In particular, the term LED refers to light emitting diodes of all types (including semiconductor and organic light emitting diodes) that may be configured to generate radiation in one or more of the infrared spectrum, ultraviolet spectrum, and various portions of the visible spectrum (generally including radiation wavelengths from approximately 400 nanometers to approximately 700 nanometers). Some examples of LEDs include, but are not limited to, various types of infrared LEDs, ultraviolet LEDs, red LEDs, blue LEDs, green LEDs, yellow LEDs, amber LEDs, orange LEDs, and white LEDs.

The term “lighting fixture” is used herein to refer to an implementation or arrangement of one or more lighting units in a particular form factor, assembly, or package, and may be associated with (e.g., include, be coupled to and/or packaged together with) other components, for example an electromagnetic (EM) ballast, in particular for supplying power.

The term “controller” is used herein generally to describe various apparatus relating to the operation of one or more light sources. A controller can be implemented in numerous ways (e.g., such as with dedicated hardware) to perform various functions discussed herein. A “processor” is one example of a controller which employs one or more microprocessors that may be programmed using software (e.g., microcode) to perform various functions discussed herein. A controller may be implemented with or without employing a processor, and also may be implemented as a combination of dedicated hardware to perform some functions and a processor (e.g., one or more programmed microprocessors and associated circuitry) to perform other functions. Examples of controller components that may be employed in various embodiments of the present disclosure include, but are not limited to, conventional microprocessors, application specific integrated circuits (ASICs), and field-programmable gate arrays (FPGAs).

In one embodiment, the present invention relates generally to a method of flood exposing a photocurable printing blank to actinic radiation from a UV light source to crosslink and cure the photocurable printing blank, the photocurable printing blank comprising a support, at least one photocurable layer upon the support, wherein the at least one photocurable layer is capable of being selectively crosslinked and cured upon exposure to actinic radiation at a desired wavelength and wherein the at least one photocurable layer comprises (a) at least one elastomeric binder, (b) at least one ethylenically unsaturated monomer, and (c) a photoinitiator having a favorable absorption profile in the desired wavelength region used for exposing the at least one photocurable layer to actinic radiation, and a photographic negative or digitally imaged mask layer disposed on the at least one photocurable layer; the method comprising the steps of:
a) positioning the photocurable printing blank in an exposure unit, wherein the exposure unit comprises a plurality of UV LED light tubes arranged in the exposure unit at a distance from a surface of the photocurable printing blank, wherein the plurality of UV LED light tubes are capable of exposing the photocurable printing blank to actinic radiation; and
b) flood exposing the photocurable printing blank through the photographic negative or the digitally imaged mask layer to actinic radiation from the plurality of UV LED light tubes;
wherein portions of the at least one photocurable layer not covered by the photographic negative or digitally imaged mask layer crosslink and cure upon exposure to actinic radiation from the UV LED light tubes to create the relief image therein.

In one embodiment, each of the UV LED light tubes in the exposure unit is connected to a suitable controller that is capable of modulating and/or controlling the output intensity of each of the plurality of UV LED light tubes. In one embodiment, each of the UV LED light tubes is adjusted and/or controlled to have an output intensity of about 5 to about 50 mW, more preferably about 10 to about 40 mW, more preferably about 25 to about 35 mW, when arranged at a distance of about 1 to about 2 inches from the surface of the photocurable printing blank.

In one embodiment, the controller provides individual control of each of the UV LED light tubes. This allows for the flood exposure to be varied across the width of the photocurable printing blank being exposed, if necessary, so that different areas of the printing blank can be custom exposed. In addition, controlling the intensity of the plurality of LED light tubes may include compensating for output power decay caused by aging of the plurality of UV LED light tubes so that the intensity remains the same across the width of the photocurable printing blank being exposed.

In one embodiment, the UV LED light tubes operate at a wavelength between about 350 nm and about 395 nm, more preferably, the UV LED light tubes operate at a wavelength between about 355 nm and about 375 nm, most preferably at about 365 nm. In one embodiment, the wavelength is controlled to within +/−5 nm.

In one embodiment, each of the UV LED light tubes has a length within a range of about 2 feet to about 10 feet, more preferably a length within a range of about 4 to about 8 feet. The opposite ends of each of the UV LED light tubes have connectors configured to allow each UV LED light tube to be installed in a socket configured to receive the UV LED light tubes. In one embodiment, the UV LED light tube is configured to have the dimensions of a standard UV fluorescent bulb and the UV LED light tube can be retrofitted into an exposure unit designed for fluorescent bulbs.

One advantage to using an UV LED tube system as described herein is that it can be used in an existing system. There are currently two types of LED tube light methods. The first is a direct plug and play system that does not require any extra wiring and the second is as system in which wiring is used to bypass the ballast. Both of these types of LED tube bulb systems can be used in the practice of the instant invention.

In one embodiment, each of the UV LED light tubes comprises at least one or at least two or at least three rows of LED chips arranged along the length of the UV LED light tube. In addition, in one embodiment, each of the rows of LED chips is preferably arranged on the same plane, meaning that there is no curvature or angles between the different rows of LED chips in the UV LED light tube. Because the UV LED light tubes are generally closely arranged within the exposure unit, the arrangement of the rows of LED chips on the same plane allows for overlapping exposure from the multiple LED light tubes exposing the surface of the photocurable printing blank. Alternatively, the rows of LED chips are arranged on different planes or at an angle to each other in order to adjust the angle of the light.

In one embodiment the LED chips are positioned on a circuit board that extends the length of the UV LED light tube. The circuit board may be mounted on or otherwise connected with a base that includes a heat that is made of metal, which metal is preferably aluminum or an aluminum alloy. The LED chips are preferably connected in series. In one embodiment, each row of LED chips is separately connected in series to the circuit board to allow for individual operation of each row of LED chips.

In one embodiment, the UV LED chips are spaced apart at a distance of about 0.25 inches to about 2 inches, more preferably about 0.5 to about 1 inches along the length of the UV LED light tube. The spacing of the LED chips will depend in part on the size and intensity of the individual chips as well as the number of rows of LED chips in the UV LED tube.

The plurality of UV LED light tubes generally comprises at least 5 UV LED light tubes, or at least 10 UV LED light tubes, or at least 20 UV LED light tubes, or at least 30 UV LED light tubes so the plurality of UV LED light tubes extends over the entire surface of the photocurable printing blank situated in the exposure unit. This allows the plurality of UV LED light tubes to be fixedly mounted so that the plurality of UV LED light tubes do not move relative to each other during the flood exposure step. These UV LED light tubes may be spaced apart at a distance of about 1 inch to about 4 inches, more preferably at a distance of about 1.5 to about 3 inches on center along the length of the UV LED light tube.

What is important is that the UV LED tubes have a wavelength within the range of 350 nm to 395 nm, preferably a wavelength of 365 nm and operate an intensity between 10 mW and 40 mW, preferably between about 25 mW and about 35 mW, or at about 30 mW.

The light emitting side of the UV LED tubes is preferably covered with a UV-transmissive cover to protect the LED chips from dust and solvents. The UV-transmissive cover may comprises a polymer such as polymethylmethacrylate or other similar material. The cover generally has a semi-cylindrical shape and extends along the entire length of the UV-LED light tube. The cover may be attached to the base by any means known in the art, including, for example, an adhesive, which may be a UV-curable adhesive.

Once the photocurable printing blank has been flood exposed to actinic radiation by the method described herein, the resulting relief image printing element can be developed to remove the uncrosslinked and/or uncured photopolymer and reveal the relief image therein.

### Example

Photocurable printing blanks were prepared comprising a photocurable layer on a support layer and the photoinitiator was selected for exposure at a 365 nm wavelength. The photocurable printing blanks were then imaged using an LED light bar system operating at a wavelength of 365 nm and a LED bank light table system operating at a wavelength of 365 nm in accordance with the invention for a suitable exposure time to achieve the desired image.

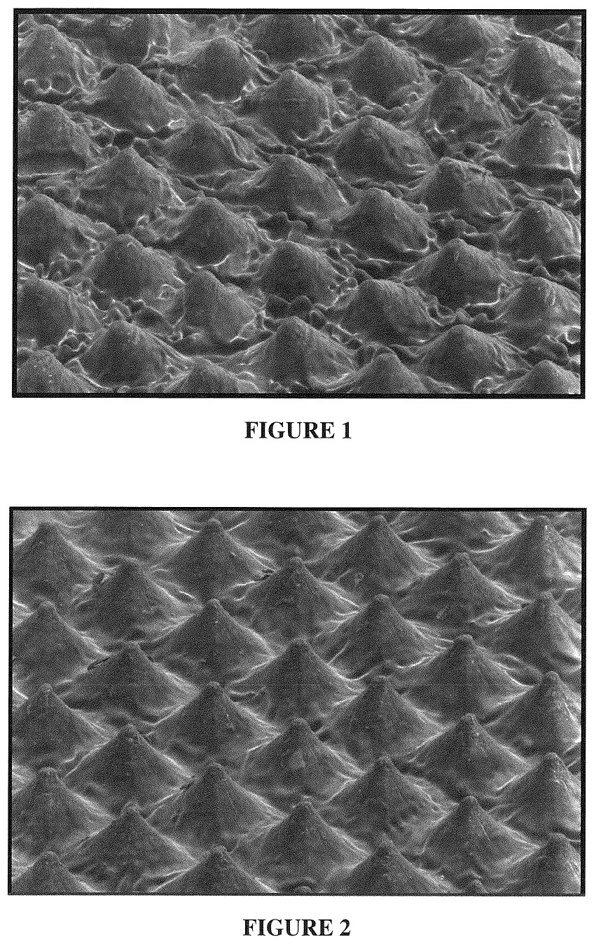

The plates were imaged to create 1% dots, 5% dots, 50% dots and 15 mil reverse images and the results are shown in FIG. 1-8.

The exposure time for the LED light bar system was 12 minutes, while the exposure time for the LED bank light table system was only 5 minutes. So, the time required for exposure using the system of the instant invention was less than half of the time required using an LED light bar system.

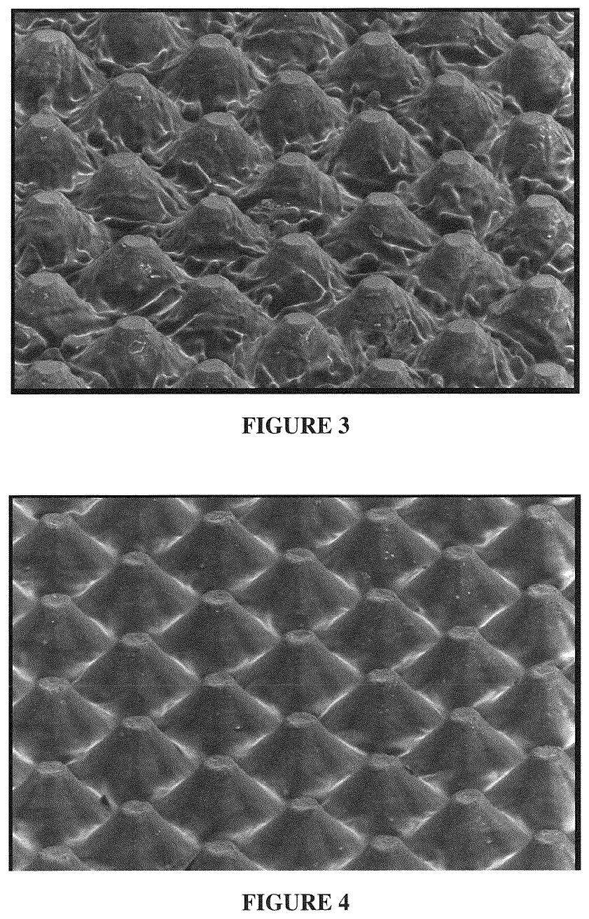

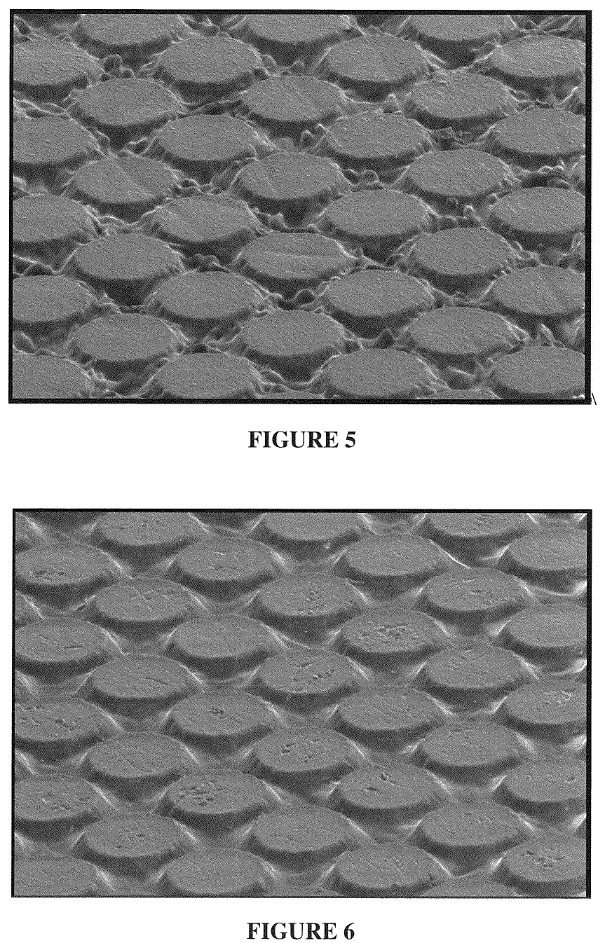

FIG. 1 depicts 1% dots imaged using the LED light bar system while FIG. 2 depicts 1% dots imaged using the LED bank light table system. Similarly FIGS. 3 and 4 depict 5% dots imaged using the LED light bar system versus the LED bank light table system and FIGS. 5 and 6 depict 50% dots imaged using the LED light bar system versus the LED bank light table system. As seen from FIGS. 1, 3, and 5, the image quality is significantly worse when using the LED light bar system as compared with the image quality achieve with the LED light bar system as shown in FIGS. 2, 4, and 6.

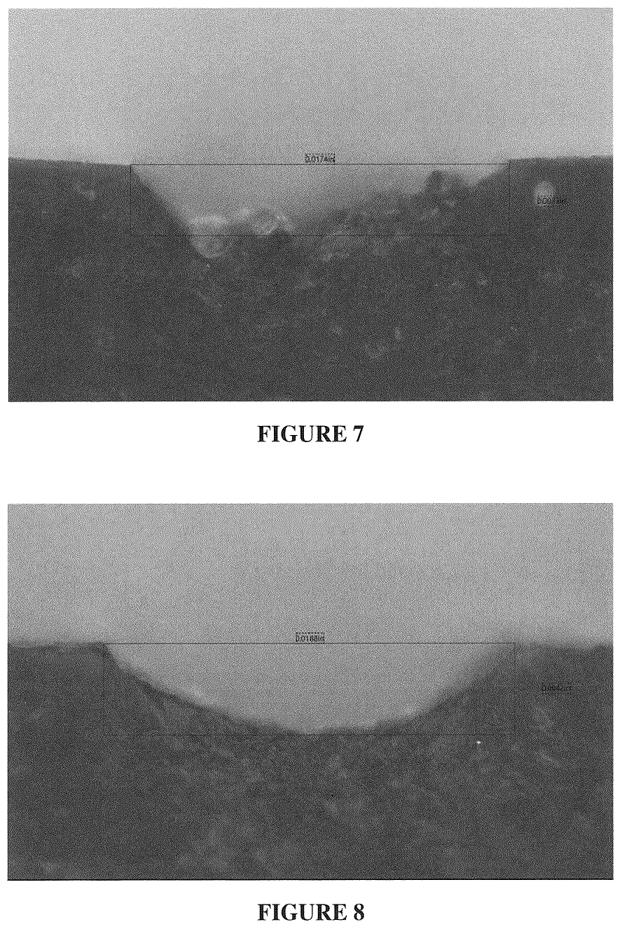

FIGS. 7 and 8 show a similar result for dot clean out and reverse depth. As shown in FIG. 7, the dot clean out and reverse depth is much worse when cured with the light bar system as compared with the LED bank light system as shown in FIG. 8.

As shown in the Example, the inventors of the present invention have demonstrated that the method described herein that incorporates the use of an exposure system and includes the plurality of UV LED light tubes is capable of producing a high quality flexographic relief image printing plate in less time and in a reproducible manner as compared with exposure systems of the prior art. The claimed method overcomes the deficiencies of printing plates produced using prior art fluorescent bulbs and can be modified and optimized to produce a good result with all types of relief image printing plates.

In addition, while the method is described in the context of sheet polymers, it is also believed that the exposure unit described herein could be used to produce relief image printing elements from liquid photopolymers.

Finally, it should also be understood that the following claims are intended to cover all of the generic and specific features of the invention described herein and all statements of the scope of the invention that as a matter of language might fall there between.

1. A method of flood exposing a photocurable printing blank to actinic radiation from a UV light source to crosslink and cure the photocurable printing blank, the photocurable printing blank comprising a support, at least one photocurable layer upon the support, wherein the at least one photocurable layer is capable of being selectively crosslinked and cured upon exposure to actinic radiation at a desired wavelength and wherein the at least one photocurable layer comprises (a) at least one elastomeric binder, (b) at least one ethylenically unsaturated monomer, and (c) a photoinitiator having an absorption profile in the desired wavelength region used for exposing the at least one photocurable layer to actinic radiation, and a photographic negative or digitally imaged mask layer disposed on the at least one photocurable layer; the method comprising the steps of:
a) positioning the photocurable printing blank in an exposure unit, wherein the exposure unit comprises a plurality of UV LED light tubes arranged in the exposure unit at a distance from a surface of the photocurable printing blank and connected to a controller that is capable of modulating and/or controlling output intensity of each of the plurality of UV LED light tubes, wherein the plurality of UV LED light tubes are capable of exposing the photocurable printing blank to actinic radiation; and
b) flood exposing the photocurable printing blank through the photographic negative or the digitally imaged mask layer to actinic radiation from the UV LED light tubes;
wherein portions of the at least one photocurable layer not covered by the photographic negative or digitally imaged mask layer crosslink and cure upon exposure to actinic radiation from the UV LED light tubes to create the relief image therein;
wherein the controller provides individual control of each of the plurality of UV LED light tubes, and
wherein each of the plurality of UV LED light tubes is modulated and/or controlled to have an output intensity of about 5 to about 50 mW/cm² when arranged at a distance of about 1 to about 2 inches from the surface of the photocurable printing blank.

2. The method according to claim 1, wherein the plurality of UV LED light tubes and photocurable printing blank do not move relative to each other during the flood exposure step.

3. (canceled)

4. The method according to claim 1, wherein each of the UV LED light tubes is modulated and/or controlled to have an output intensity of about 10 to about 40 mW/cm² when arranged at the distance of about 1 to about 2 inches from the surface of the photocurable printing blank.

5. The method according to claim 4, wherein each of the UV LED light tubes is modulated and/or controlled to have an output intensity of about 25 to about 35 mW/cm² when arranged at the distance of about 1 to about 2 inches from the surface of the photocurable printing blank.

6. The method according to claim 1, wherein the UV LED light tubes operate at a wavelength between about 350 nm and about 395 nm.

7. The method according to claim 6, wherein the UV LED light tubes operate at a wavelength between about 355 nm and about 375 nm.

8. The method according to claim 1, wherein each of the UV LED light tubes has a length within a range of about 2 feet to about 10 feet.

9. The method according to claim 8, wherein each of the UV LED light tubes has a length within a range of about 4 to about 8 feet.

10. The method according to claim 1, wherein each of the UV LED light tubes comprises at least three rows of LED chips arranged along the length of the UV LED light tube.

11. The method according to claim 1, wherein the UV LED chips are spaced apart at a distance of about 0.25 inches to about 2 inches along the length of the UV LED light tube.

12. The method according to claim 11, wherein the UV LED chips are spaced apart at a distance of about 0.5 to about 1 inches along the length of the UV LED tube light.

13. The method according to claim 1, wherein the plurality of UV LED light tubes comprises at least 5 UV LED light tubes.

14. The method according to claim 13, wherein the plurality of UV LED light tubes comprises at least 10 UV LED light tubes.

15. The method according to claim 14, wherein the plurality of UV LED light tubes comprises at least 20 UV LED light tubes.

16. The method according to claim 15, wherein the plurality of UV LED light tubes comprises at least 30 UV LED light tubes.

17. The method according to claim 13, wherein the UV LED light tubes are spaced apart at a distance of about 1 inch to about 4 inches on center along the length of the UV LED light tube.

18. The method according to claim 17, wherein the UV LED light tubes are spaced apart at a distance of about 1.5 to about 3 inches on center along the length of the UV LED light tube.

19. The method according to claim 1, wherein each of the plurality of UV LED light tubes are controlled to compensate for output intensity decay.

20. The method according to claim 1, wherein the flood exposure time is at most 5 minutes.

21. The method according to claim 10, wherein each row of LED chips is separately connected in series to allow for individual operation of each row of LED chips.

22. The method according to claim 10, wherein each row of LED chips is arranged on a different plane or at an angle with respect to another row of LED chips in order to adjust the angle of the light emitted from the UV LED light tubes.
